(19) United States
(12) Patent Application Publication
(10) Pub. No.: US 2019/0179191 A1
(43) Pub. Date: Jun. 13, 2019

(54) DISPLAY DEVICE INCLUDING A LIGHT-EMITTING DIODE PACKAGE

(71) Applicant: SAMSUNG DISPLAY CO., LTD., YONGIN-SI (KR)

(72) Inventors: SEOHYEON CHOI, Hwaseong-si (KR); Jeongweon SEO, Hwaseong-si (KR); Seonghyun GO, Yongin-si (KR)

(21) Appl. No.: 16/130,415

(22) Filed: Sep. 13, 2018

(30) Foreign Application Priority Data
Dec. 12, 2017 (KR) 10-2017 -0170444

(51) Int. Cl. G02F 1/1333; G02F 1/1335; F21V 8/00; H01L 33/62; G02F 1/1362

(52) U.S. Cl. CPC G02F 1/133308; G02F 1/133603; G02B 6/0073; G02F 1/136286; G02B 6/0025; H01L 33/62; G02B 6/0068

(57) ABSTRACT

A display device includes a display panel and a backlight unit adjacent to the display panel. A cover unit is adjacent to the display panel and the backlight unit. The backlight unit includes a light guiding structure including a first surface and a second surface facing each other in a thickness direction of the display panel. Side surfaces connect the first surface to the second surface. Signal lines are directly disposed on the first surface, the second surface, or a side surface of the side surfaces. A light-emitting diode package is coupled to the signal lines and is positioned to provide light to a. first side surface of the side surfaces.

### CROSS-REFERENCE TO RELATED APPLICATION

This U.S. non-provisional patent application claims priority under 35 U.S.C. § 119 to Korean Patent Application No. 10-2017-0170444, filed on Dec. 12, 2017, in the Korean intellectual Property Office, the disclosure of which is incorporated by reference herein in its entirety.

### Technical Field

Exemplary embodiments of the present invention relate to a display device, and more particularly, to a display device including a. light-emitting diode package.

### Discussion of Related Art

In general, display devices may include transmissive, transfiective, or reflective display devices. Each of the transmissive and transflective display devices may include a display panel displaying an image, a backlight unit providing light to the display panel, and a cover unit protecting the display panel.

The backlight unit may include a light source, which is configured to generate light, and a light guiding structure, which is configured to provide the light from the light source toward the display panel. The relative configuration between the light source and the light guiding structure may be variously changed depending on the shape of the display device.

### SUMMARY

An exemplary embodiment of the present invention provides display device, in which a light guiding structure and a light source are integrated into a single object or a single structure.

According to an exemplary embodiment of the present invention, a display device includes a display panel and a backlight unit adjacent to the display panel. A cover unit is adjacent to the display panel and the backlight unit. The backlight unit includes a light guiding structure including a first surface and a second surface facing each other in a thickness direction of the display panel. Side surfaces connect the first surface to the second surface. Signal lines are directly disposed on the first surface, the second surface, or a side surface of the side surfaces. A light-emitting diode package is coupled to the signal lines and is positioned to provide light to a first side surface of the side surfaces.

In an exemplary embodiment of the present invention, the signal lines may include a first signal line, and a second signal line spaced apart from the first signal line. A portion of the first or second signal lines may be disposed on the first side surface. The light-emitting diode package may be coupled to the portion of the first or second signal lines disposed on the first side surface.

In an exemplary embodiment of the present invention, the signal lines may include a first signal line, and a second signal line spaced apart from the first signal line. The first signal line may include a first line portion disposed on the first surface and a first coupling portion disposed on the first side surface. The second signal line may include a second line portion disposed on the second surface and a second coupling portion disposed on the first side surface. The light-emitting diode package may he coupled to the first coupling portion and the second coupling portion.

In an exemplary embodiment of the present invention, the first side surface may be defined by the thickness direction of the display panel and a length direction crossing the thickness direction of the display panel. The first coupling portion and the second coupling portion may be spaced apart from each other in the length direction.

In an exemplary embodiment of the present invention, the display panel may include a display region, on which pixels are provided, and a non-display region, on which the pixels are not provided. The first line portion and the second line portion may be overlapped with the non-display region.

In an exemplary embodiment of the present invention, the light-emitting diode package may include a mold, in which a cavity is defined. A light-emitting diode may be disposed in the cavity and may include a first electrode and a second electrode. A sealing element may substantially cover the light-emitting diode. A first lead frame may be connected to the first electrode and may include a first lead frame coupling portion disposed on an outer surface of the mold. A second lead frame may be connected to the second electrode and may include a second lead coupling portion disposed on the outer surface of the mold.

In an exemplary embodiment of the present invention, the display device may include a solder paste connecting the first lead coupling portion and the second lead coupling portion to the signal lines.

In an exemplary embodiment of the present invention, the first lead coupling portion and the solder paste may be disposed between a corresponding signal line of the signal lines and the mold.

In an exemplary embodiment of the present invention, the light-emitting diode package may include a heat dissipation unit coupled to the mold and in direct contact with the cover unit.

In an exemplary embodiment of the present invention, the signal lines may include a first signal line including a first line portion disposed on the first surface and a first coupling portion disposed on the first surface. A second line portion may be disposed on the second surface and a second signal line disposed on the second surface. The light-emitting diode package may be coupled to the first coupling portion and the second coupling portion.

In an exemplary embodiment of the present invention, the light-emitting diode package may include a mold, in which a cavity is defined. The mold may include a body portion, a first sidewall portion, and a second sidewall portion. The first sidewall portion and the second sidewall portion may be connected to the body portion and may be overlapped with the first surface and the second surface, respectively. A light-emitting diode may be disposed in the cavity. The light-emitting diode may include a first electrode and a second electrode. A sealing element may substantially cover the light-emitting diode. A first lead frame may be disposed on the first sidewall portion and may electrically connect the first electrode to the first coupling portion. A second lead frame may be disposed on the second sidewall portion and may electrically connect the second electrode to the second coupling portion.

In an exemplary embodiment of the present invention, a portion of the first lead frame may be disposed on an inner surface of the first sidewall portion facing the first surface. A portion of the second lead frame may be disposed on an inner surface of the second sidewall portion facing the second surface.

In an exemplary embodiment of the present invention, the display panel may include a display region, on which pixels are provided, and a non-display region, on which the pixels are not provided. The first signal line and the second signal line may be overlapped with the non-display region.

In an exemplary embodiment of the present invention, the display device may include a circuit board, which is configured to provide a first voltage and a second voltage, which are different from each other, to the signal lines. The signal lines may include a first signal line, to which the first voltage is applied, and a second signal line, to Which the second voltage is applied. Each of the first signal line and the second signal line may include a coupling portion coupled to the circuit board. The coupling portion may be disposed on a second side surface of the side surfaces adjacent to the first side surface.

In an exemplary embodiment of the present invention, the light guiding structure may include a glass substrate.

In an exemplary embodiment of the present invention, the display device may include a color conversion layer. The color conversion layer may be disposed between the display panel and the light guiding structure and may include a quantum dot.

In an exemplary embodiment of the present invention, the light-emitting diode package may be configured to emit a blue light. The quantum dot may include a first quantum dot, which is configured to absorb the blue light and emit a green light, and a second quantum dot, which is configured to absorb the blue light and emit a red light.

In an exemplary embodiment of the present invention, the light-emitting diode package may be configured to emit a blue light. The light-emitting diode package may include a light-emitting diode and a sealing element covering the light-emitting diode. The sealing element may include a fluorescent material, which is mixed therein and is configured to absorb the blue light and emit one of red and green lights. The quantum dot may be configured to absorb the blue light and to emit the other of the red and green lights.

According to an exemplary embodiment of the present invention, a display device includes a first base substrate including a first surface and a second surface facing each other in a thickness direction. Side surfaces connect the first surface to the second surface to each other. A second base substrate is disposed on the first base substrate. A liquid crystal layer is disposed between the first and second base substrates. Signal lines are directly disposed on the first surface, the second surface, or a corresponding side surface of the side surfaces. A light-emitting diode package is coupled to the signal lines and is positioned to provide light to a side surface of the side surfaces.

In an exemplary embodiment of the present invention, the light-emitting diode package may include a mold, in which a cavity is defined. A light emitting diode may be disposed in the cavity. The light-emitting diode may include a first electrode and a second electrode. A sealing element may substantially cover the light-emitting diode. A first lead frame may be connected to the first electrode. The first lead frame may include a first lead coupling portion, which is disposed on a surface of the mold and is coupled to a first signal line of the signal lines. A second lead frame may be connected to the second electrode. The second lead frame may include a second lead coupling portion., which is disposed on the surface of the mold and is coupled to a second signal line off the signal lines.

According to an exemplary embodiment of the present invention, a light-emitting diode package includes a mold including a cavity formed in the mold. A light-emitting diode is disposed on the mold. A sealing element is disposed on side surfaces of the cavity. The sealing element substantially covers the light-emitting diode. A first lead frame is disposed on the mold. The first lead frame includes a first lead coupling portion disposed on a surface of the mold facing away from the light-emitting diode. A second lead frame is disposed on the mold. The second lead frame includes a second lead frame coupling portion disposed on the surface of the mold facing away from the light-emitting diode. The second lead frame coupling portion is spaced apart from the first lead frame coupling portion.

In an exemplary embodiment of the present invention, the first lead frame coupling portion or the second lead frame coupling portion may be in direct contact with a side surface of the sealing element.

### BRIEF DESCRIPTION OF THE DRAWINGS

The above and other features of the present invention will become more apparent by describing in detail exemplary embodiments thereof with reference to the accompanying drawings, in which:

FIG. 1 is a perspective view of a display device according to an exemplary embodiment of the present invention.

FIG. 2 is an exploded perspective view of a display device according to an exemplary embodiment of the present invention.

FIG. 3 is a cross-sectional view of a portion of a display device according to an exemplary embodiment of the present invention.

FIG. 4 is an exploded perspective view of a backlight unit according to an exemplary embodiment of the present invention.

FIG. 5A is a plan view of a light-emitting diode package according to an exemplary embodiment of the present invention.

FIG. 5B is a cross-sectional view taken along line of FIG. 1.

FIG. 6A is an equivalent circuit diagram of a connection structure of a light-emitting diode package according to an exemplary embodiment of the present invention.

FIGS. 6B and 6C are each cross-sectional views of a portion of a backlight unit according to an exemplary embodiment of the present invention.

FIG. 6D is an enlarged cross-sectional view of a portion of a display device according to an exemplary embodiment of the present invention.

FIG. 6E is an equivalent circuit diagram of a connection structure of a light-emitting diode package according to an exemplary embodiment of the present invention.

FIG. 7A is an exploded perspective view of a backlight unit according to an exemplary embodiment of the present invention.

FIG. 7B is an equivalent circuit diagram of a connection structure of a light-emitting diode package according to an exemplary embodiment of the present invention.

FIG. 7C is a cross-sectional view of a portion of a backlight unit according to an. exemplary embodiment of the present invention.

FIG. 8A is an exploded perspective view of a backlight unit according to an exemplary embodiment of the present invention.

FIG. 8B is a cross-sectional view of a light-emitting diode package according to an exemplary embodiment of the present invention.

FIG. 8C is a cross-sectional view of a portion of a backlight unit according to an exemplary embodiment of the present invention.

FIG. 9 is a cross-sectional view of a portion of a backlight unit according to an exemplary embodiment of the present invention.

FIG. 10 is a cross-sectional view of a display device according to an exemplary embodiment of the present invention.

Since the drawings in the Figures above are intended for illustrative purposes, the elements in the drawings are not necessarily drawn to scale. For example, some of the elements may be enlarged or exaggerated for clarity of description.

### DETAILED DESCRIPTION

Exemplary embodiments of the present invention will be described below in more detail with reference to the accompanying drawings. In this regard, the exemplary embodiments may have different forms and should not be construed as being limited to the exemplary embodiments of the present invention described herein. Like reference numerals may refer to like elements throughout the specification and drawings.

It will be understood that when a component, such as a layer, a film, a region, or a plate, is referred to as being “on” another component, the component may be directly on the other component or intervening components may be present,

It will be understood that although the terms “first” and “second” may be used herein to describe various components, these components should not be limited by these terms.

As used herein, the singular forms “a” an and “the” may include the plural forms as well, unless the context clearly indicates otherwise.

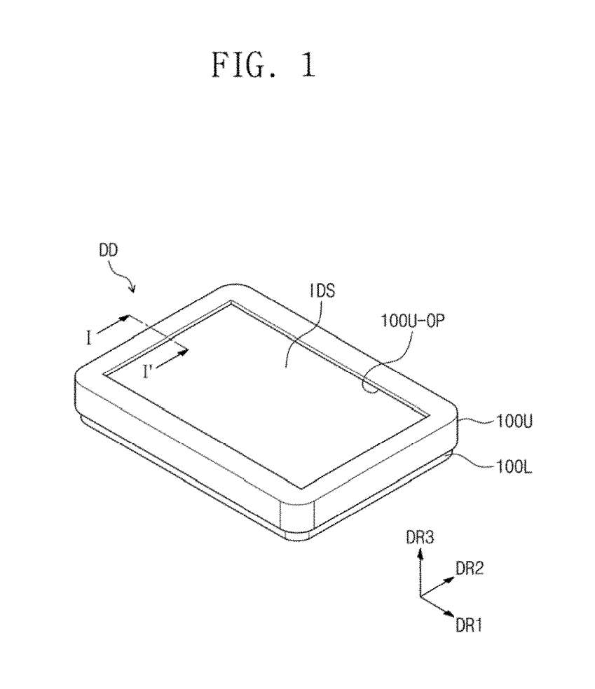

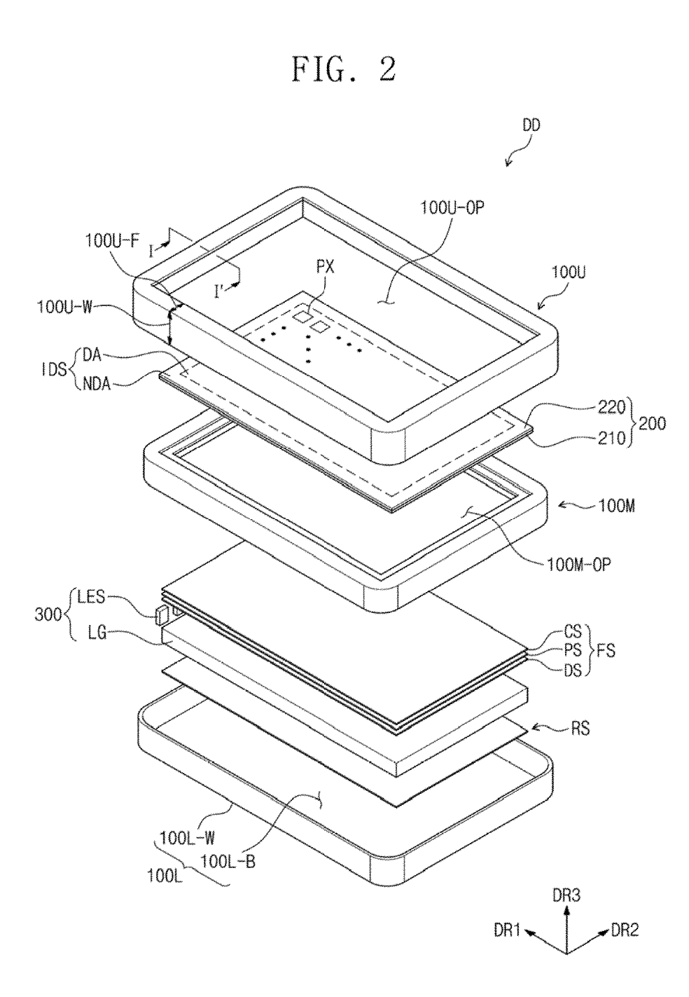

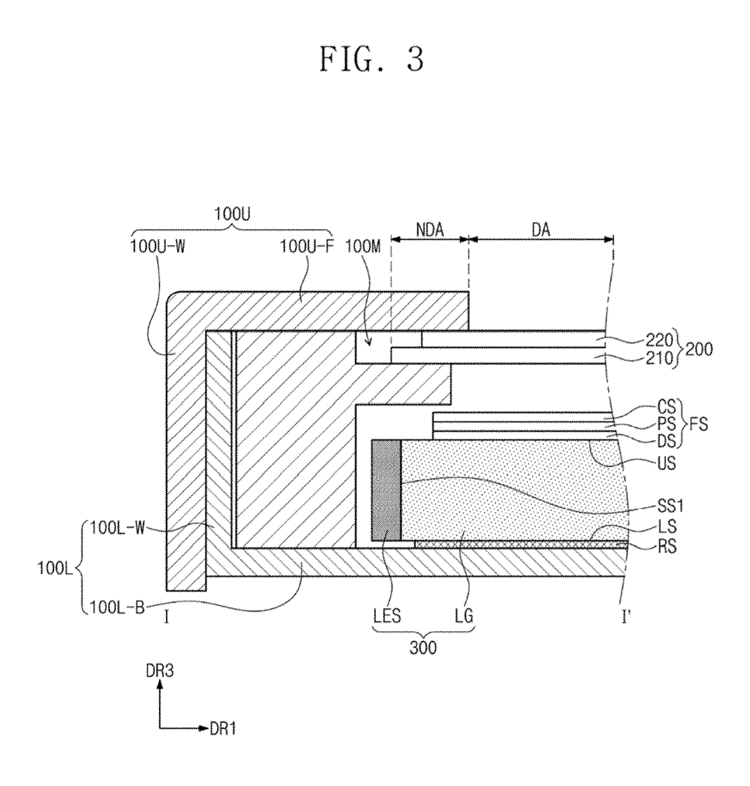

FIG. 1 is a perspective view illustrating a display device according to an exemplary embodiment of the present invention, FIG. 2 is an exploded perspective view of a display device according to an exemplary embodiment of the present invention. FIG. 3 is a cross-sectional view of a portion of a display device according to an exemplary embodiment of the present invention.

Referring to FIG. 1, in an exemplary embodiment of the present invention, a display device DD may be part of a television set, such as a flat screen television, However, exemplary embodiments of the present invention are not limited thereto, and the display device DD may be a part of an electronic device such as a monitor, a notebook computer, a tablet computer, or a gaming machine. However, it should be understood that these are merely examples and that the display device DD may be used for other electronic devices.

The display device DD may include a display surface IDS defined by two different directions (e.g., a first direction axis DR1 and a second direction axis DR2). A direction orthogonal to the display surface IDS may be referred to herein as a third direction axis :DR3, The third direction axis DR3 may be used as a criterion for distinguishing a top or front surface from a bottom or rear surface hereit . Herein, first to third directions may be directions indicated by the first to third direction axes DR1, DR2, and DR3, respectively, and will be identified with the same reference numbers. Thus, the first direction axis DR1 may be interchangeably referred herein to as a first direction DR1, the second direction axis DR2 may be interchangeably referred to herein as a second direction DR2, and the third direction axis DR3 may be referred to as a third direction DR3. The first direction DR1 and the second direction DR2 perpendicular to the first direction DR1 may define a plane along with the display surface IDS, for example, extends. The third direction may be perpendicular to (e.g., orthogonal to) each of the first and second. directions DR1 and DR2. In an exemplary embodiment of the present invention, the display device DD may have a substantially fiat structure, but the display surface IDS may have a curved structure. For example, the display device may be a bendable or foldable display device that is in a curved or bent state at some times and is in a substantially flat state at other times. Alternatively, the display device may be in a permanently folded, curved or bent state.

Referring to FIGS. 1 to 3, the display device DD may include cover units 100U, 100M, and 100L, a display panel 200, and a backlight unit 300. The display device DD may be a transmissive or transfiective type of display device, which may be configured to show an image using light. Light may be generated by the backlight unit 300 (e.g., to display an image).

The cover units 100U, 100M, and 100L may include a top cover 100U, a bottom cover 100L, and a supporting frame 100M. The top cover 100U and the bottom cover 100L may he coupled to each other, thus defining an exterior appearance of the display device DD. For example, the shape (e.g., curved or flat) of the display device DD may be determined by the top cover 100U and the bottom cover 100L. Other elements of the display device DD may be disposed in an internal space, which is defined by the top cover 100U and the bottom cover 1001,. In an exemplary embodiment of the present invention, at least one of the top cover 100U, the bottom cover 100L, and the supporting frame 100M may be omitted. According to an exemplary embodiment of the present invention, any combination of the top cover 100U, the bottom cover 100L, and/or the supporting frame 100M may be referred to as a cover unit herein.

The top cover 100U may be disposed on the bottom cover 100L. The top cover 100U may be disposed to expose a region of the display surface IDS. For example, the top cover 100U may include an opening 100U-OP, which is formed to expose a region of the display surface IDS (e.g., a display region DA, which is used to display an image). The top cover 100U may cover a non-display region NDA of the display surface IDS. The non-display region NDA might not be used to display an image and may be provided to enclose the display region DA. However, the arrangement of the non-display region NDA and the display region DA is not limited to the above example. As an example, the non-display region may be arranged at four sides of the display surface IDS in a plan view; however, exemplary embodiments of the present invention are not limited thereto. For example, the non-display region NDA may be arranged at less than four sides (e.g., two sides or three sides) of the display surface IDS in a plan view.

The top cover 100U may include a sidewall 100U-W (which may be referred to herein as a first sidewall), which may be an outer side surface of the display device DD, and a front portion 100U-F, which may be extended from the first sidewall 100U-W and may be overlapped with the display panel 200. The top cover 100U may include the first sidewall 100U-W and the front portion 100U-F; however, exemplary embodiments of the present invention are not limited thereto. For example, the top cover 100U may be provided to have only the first sidewall 100U-W. As an example, the top cover 100IJ may be coupled to the bottom cover 100L; however, exemplary embodiments of the present invention are not limited to a specific shape of the top cover 100U. In an exemplary embodiment of the present invention, the top cover 100U may be omitted.

The bottom cover 100L may be disposed below the display panel 200. The bottom. cover 100L may include a bottom portion 100L-B and a sidewall 100L-W (Which may be referred to herein. as a second sidewall) extending upwardly from an edge of the bottom portion 100L-B.

The top cover 100U and the bottom cover 100L may be manufactured using a mold and a press machine. For example, a metal plate may be disposed on the mold, and then, the metal plate may be pressed by the press machine. As a result, the bottom cover 100L may be manufactured to have a shape resembling an internal space of the mold.

The supporting frame 100M may be disposed between the top cover 100U and the bottom cover 100L. The supporting frame 100M may be disposed on the bottom portion 100L-B. An opening 100M-OP may be provided in the supporting frame 100M. In an exemplary embodiment of the present invention, the supporting frame 100M may be provided to support the display panel 200 and to have a rectangular shape. Alternatively, the display panel 200 may have a square shape; however, exemplary embodiments of the present invention are not limited to a display panel 200 having a particular shape.

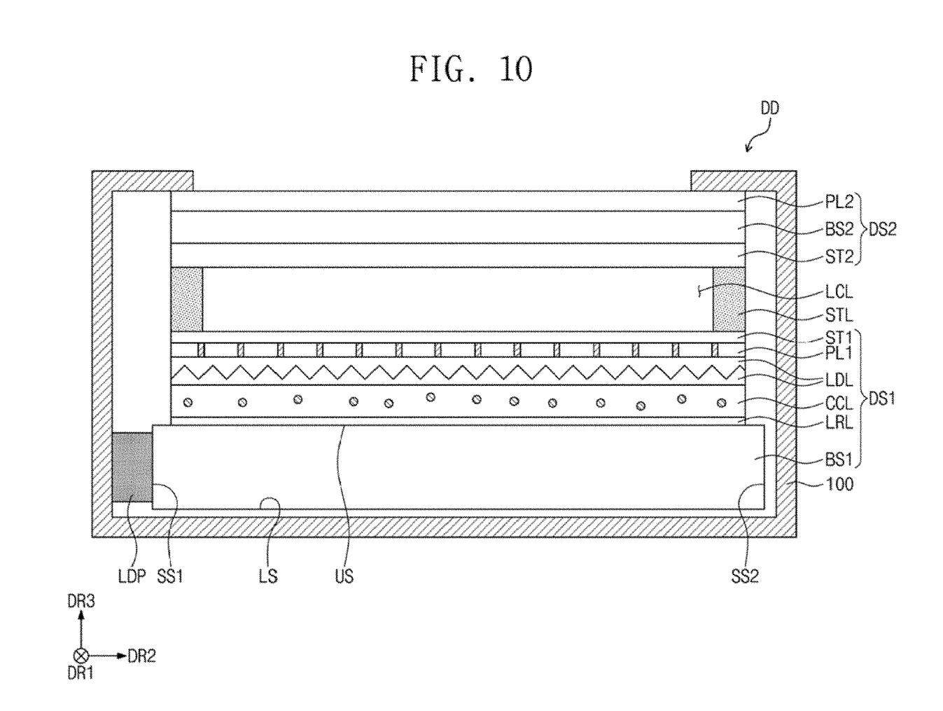

The display panel 200 may receive light from the backlight unit 300. The display panel 200 may include the display region DA, in which a pixel PX is provided and the non-display region NDA, in which the pixel PX is not provided. A plurality of pixels PX may he arranged in the display region DA. The plurality of pixels PX may be spaced apart from each other in the first and second directions DR1 and DR2, and may be arranged in a plurality of rows and columns to have a matrix configuration. The display panel 200 may be a liquid crystal display panel, an electrophoretic display panel, or an clectrowetting display panel. In an exemplary embodiment of the present invention, the display panel 200 may be a liquid crystal display panel including a first substrate 210, a second substrate 220, and a liquid crystal layer (see, e.g., FIG. 10) between the first and second substrates 210 and 220.

The backlight unit 300 may include a light source LES, which is configured to generate light, a light guiding structure LG, which is positioned, shaped and dimensioned to guide the light from the light source LES toward the display panel 200, and a signal line, which is disposed in the light guiding structure LG and is used to provide electrical signals to the light source LES.

The light source LES may include a light-emitting diode package. The signal line may be directly disposed on the light guiding structure LG, and the light-emitting diode package may be coupled to the light guiding structure LG through a signal line.

The light guiding structure LG maybe adjacent to the display panel 200. For example, the light guiding structure LG may be disposed below the display panel 200 (e.g., along the third direction DR3) and may include a first surface US, a second surface LS, and a plurality of side surfaces (e.g., or connection surfaces) connecting the first surface US and the second surface LS, The light guiding structure LG may be a tetragonal or rectangular plate; however, exemplary embodiments of the present invention are not limited thereto.

The first surface US and the second surface LS may face each other in a thickness direction of the display panel 200 or in the third direction DR3. The first surface US may be a surface, from which light incident into the light guiding structure LG will be emitted. The first surface US may face the display panel 200. The second surface LS may face the bottom portion 100L-B. A side surface of the side surfaces may face the light source LES. The side surface of the side surfaces may be referred to as a first side surface, a light incident surface or an incidence surface.

The display device DD may include optical sheets FS and a reflection sheet RS, which are configured to increase efficiency of light to be disposed to the display panel 200. The optical sheets FS may be disposed between the first surface US of the light guiding structure LG and the display panel 200.

The optical sheets FS may include a diffusion sheet DS, a prism sheet PS, and a protection sheet CS. The diffusion sheet DS may be configured to diffuse light, which is emitted through the first surface US of the light guiding structure LG. The prism sheet PS may be configured to condense light, which is emitted from the first surface US of the light guiding structure LG and propagates in a direction normal to the display panel. 200. The protection sheet CS may he configured to protect the prism sheet PS. As an example, a bottom surface of the diffusion sheet DS may be in direct contact with the first surface US. A bottom surface of the prism sheet PS may be in direct contact with an upper surface of the diffusion sheet DS facing away from the first surface US. An upper surface of the prism sheet PS may he in direct contact with a bottom surface of the protection sheet CS facing the first surface US.

The reflection sheet RS may be disposed below the light guiding structure LG. The reflection sheet RS may he configured to reflect light, which may be leaked through the second surface LS of the light guiding structure LG, toward the light guiding structure LG. In an exemplary embodiment of the present invention, at least one of the optical sheets FS and the reflection sheet RS may be omitted.

For example, the light-emitting diode package LDP may be coupled to a side surface of the backlight unit 300 described herein (e.g., with little or no gap between the light source LES and the light guiding structure—see, e.g., FIG. 3), thus preventing misalignment between the light guiding structure LG and the light-emitting diode package LDP, which may increase optical efficiency of the backlight unit 300.

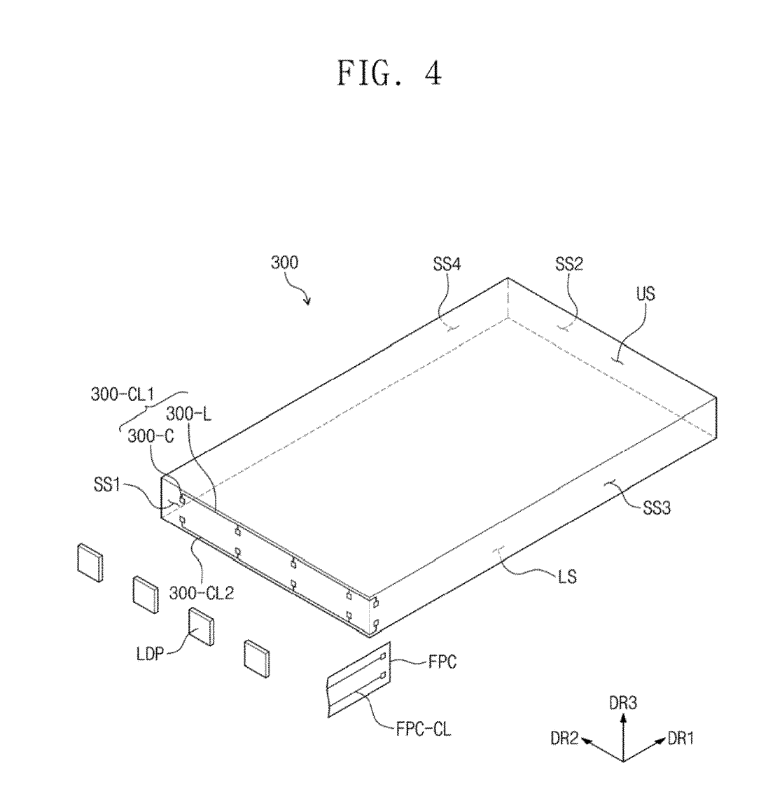

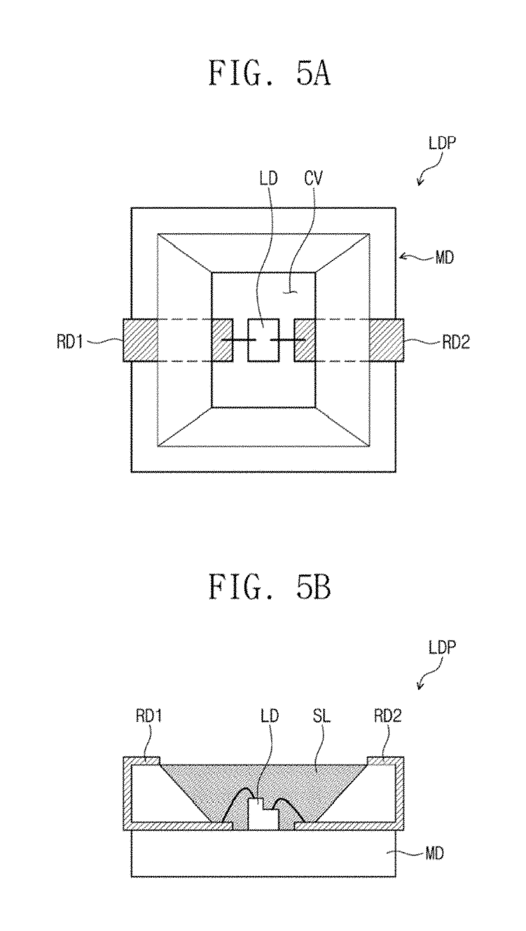

FIG. 4 is an exploded perspective view of a backlight unit according to an exemplary embodiment of the present invention. FIG. 5A is a plan view of a light-emitting diode package according to an exemplary embodiment of the present invention. FIG. 5B is a cross-sectional view taken along line I-I′ of FIG. 1. The light-emitting diode package LDP will be described. in more detail below with reference to FIGS. 4, 5A and SB as an example of the light source.

Referring to FIG. 4, the light guiding structure LG may include first, second, third and fourth side surfaces SS1, SS2, SS3 and SS4. The first and second side surfaces SS1 and SS2 may face each other in the first direction DR1, and the third and fourth side surfaces SS3 and SS4 may face each other in the second direction DR2. The light guiding structure LG may include a plastic substrate (e.g., PMMA) or a glass substrate.

Signal lines 300-CL1 and 300-CL2 may be directly disposed on the first surface US, the second surface LS, or a side surface of the first to fourth side surfaces SS1 to SS4. In an exemplary embodiment of the present invention, the first signal line 300-CL1 and/or the second signal line 300-CL2 may be disposed on the first and third side surfaces SS1 and SS3 (see, e.g., FIG. 4). As an example, the first signal line 300-CL1 and/or the second signal line 300-CL2 may be disposed on one side surface (e.g., the first side surface SS1), and not on the other side surfaces.

In an exemplary embodiment of the present invention, a conductive layer may be formed on a surface of the back light unit 300 (e.g., a side surface of the side surfaces SS1 to SS4, the first surface US or the second surface LS). The conductive layer may be formed by using a deposition method and then the conductive layer may be patterned by a patterning process including a photolithography step. A material included in the light guiding structure LG may be determined in consideration of process temperatures in the steps of forming and patterning the conductive layer. As an example, the light guiding structure LG may include a glass. In an exemplary embodiment of the present invention, a conductive paste may be printed on the corresponding surface to form the first signal line 300-CL1 and the second signal line 300-CL2.

In an exemplary embodiment of the present invention, at least a portion of the first signal lire 300-CL1 and the second signal line 300-CL2 may be disposed on the first side surface SS1. The light-emitting diode package LDP may be coupled to the portion of each of the first signal line 300-CL1 and the second signal line 300-CL2, which is disposed on the first side surface SS1.

Each of the first signal line 300-CL1 and the second signal line 300-CL2 may include a line portion 300-L and a coupling portion 300-C. In an exemplary embodiment of the present invention, a plurality of the coupling portions 300-C may be provided, and the number of the coupling portions 300-C may vary depending on the number of the light-emitting diode packages LDP.

At least one of the coupling portions 300-C may be coupled to a circuit board FPC. In an exemplary embodiment of the present invention, a pair of the coupling portions 300-C may be coupled to the circuit board FPC; however, exemplary embodiments of the present invention arc not limited thereto. Referring to FIG. 4, the pair of the coupling portions 300-C may be disposed on the third side surface SS3; however, exemplary embodiments of the present invention are not limited to the specific positions of the coupling portions 300-C. In an. exemplary embodiment of the present invention, the first signal line 300-CL1 and the second signal line 300-CL2 may be disposed on only the first side surface SSI. As an example, the signal lines FPC-CL may be arranged substantially in-parallel with each other.

The circuit board FPC may include at least one insulating layer and at least one circuit layer. The circuit layer may include signal lines FPC-CL. A signal line of the signal lines FPC-CL may be used to provide a first voltage to the first signal line 300-CLI, and a second signal line of the signal lines FPC-CL may be used to provide a second voltage, which is different from the first voltage, to the second signal line 300-CL2.

FIGS. 5A and 5B illustrate a light-emitting diode package LDP according an exemplary embodiment of the present invention. In an exemplary embodiment of the present invention, the light-emitting diode package LDP may be configured to emit a white light.

Referring to FIGS. 5A and 5B, the light-emitting diode package LDP may include a light-emitting diode LD, a first lead frame RD1, a second lead frame RD2, and a mold MD.

The light-emitting diode LD may be configured to emit light in response to a driving voltage applied through a first electrode and/or a second electrode. The light-emitting diode LD may include an n-type semiconductor layer, an active layer, and a p-type semiconductor layer, which are sequentially stacked, and if the driving voltage is applied to the light-emitting diode LD, electrons and holes may be recombined to emit the light.

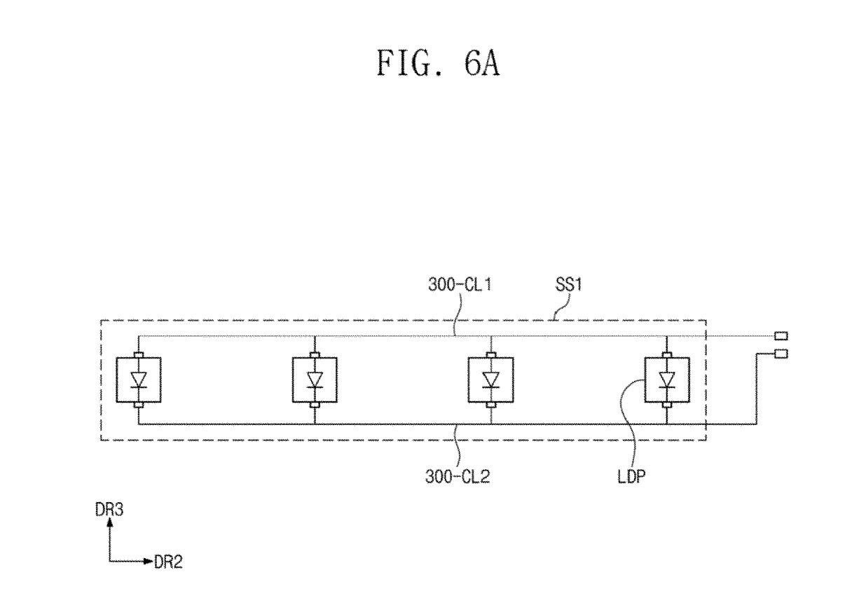

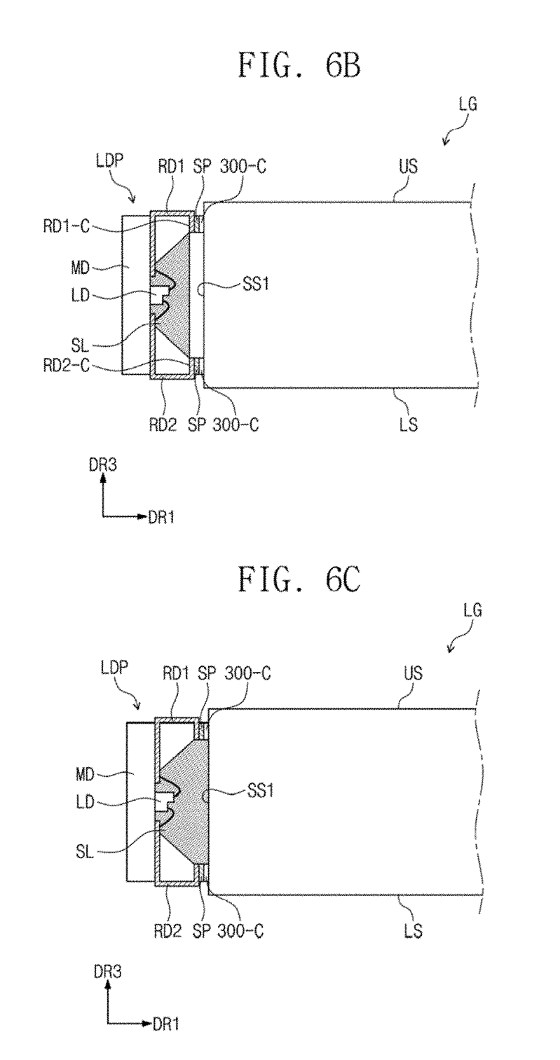

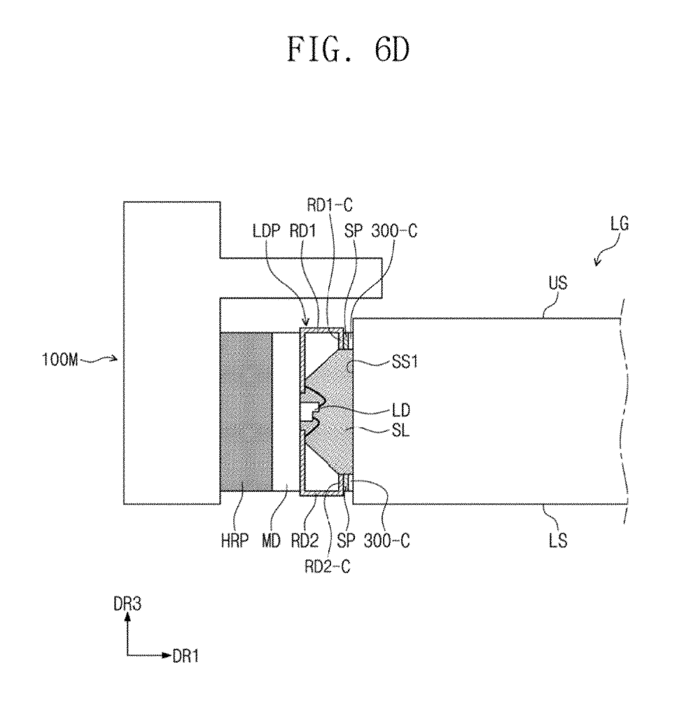

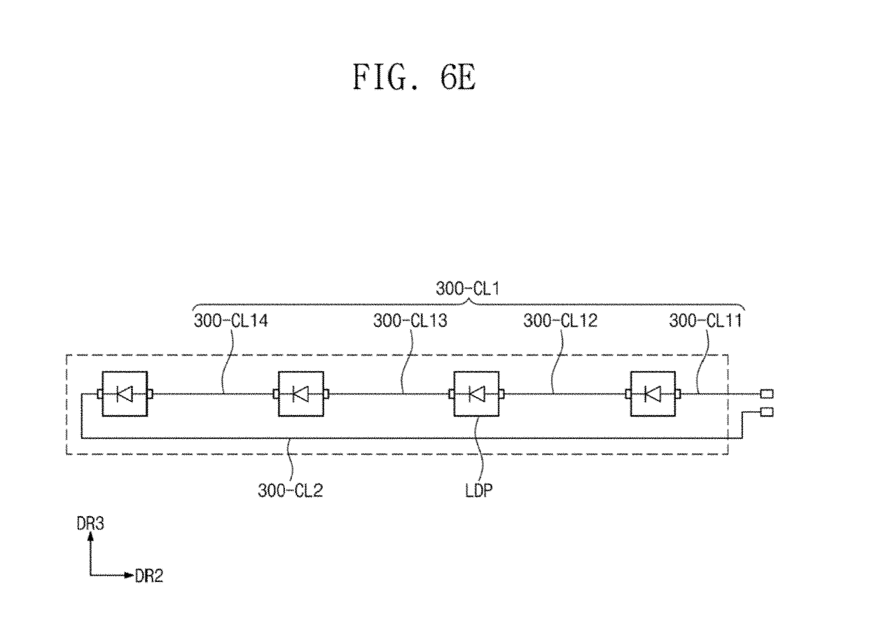

The first lead frame RD1 may be connected to the first electrode of the light-ernitting diode LD, and the second lead frame RD2 may be connected to the second electrode of the light-emitting diode LD. In an exemplary embodiment of the present invention, a wire may be used to connect the first lead frame RD1 to the first electrode (see, e.g., FIG. 5B). The light-emitting diode LD may be mounted on the mold MD and the first lead frame RD1 and the second lead frame RD2 may be fastened to the mold MD. The mold MD may be formed of or include a synthetic resin material. The mold MD may include a cavity CV. As an example, the cavity CV may have four substantially equally sized sidewalk extending at an angle with respect to the first direction DR1 and the third direction DR3 (see, e.g., FIG. 6B). The sidewalis of the cavity CV may each connect with a floor of the cavity CF which is relatively smaller than an opening of the cavity CV. The light-emitting diode LD may be disposed on the floor of the cavity CF. For example, the light-emitting diode LD may be mounted on a bottom surface of the cavity CV. A sealing element SL may be disposed in the cavity CV to substantially cover the light-emitting diode LD. The sealing element SL may be formed of or include an epoxy resin, or an acrylic resin.

A portion of each of the first lead frame RD1 and the second lead frame RD2 may be disposed on an exterior surface of the mold MD. The portion of the first lead frame RD1 exposed by the mold MD may be connected to the coupling portion 300-C of the first signal line 300-CL1 (see, e.g., FIG. 4). and the portion of the second lead frame RD2 exposed by the mold MD may be connected to the coupling portion 300-C of the second signal line 300-CL2 (see, e.g., FIG. 4).

FIG. 6A is an equivalent circuit diagram of a connection structure of a light-emitting diode package according to an exemplary embodiment of the present invention. FIGS. 6B and 6C are each cross-sectional views of a portion of a backlight unit according to an exemplary embodiment of the present invention. FIG. 61) is an enlarged cross-sectional view of a portion of a display device according to an exemplary embodiment of the present invention. FIG. 6E is an equivalent circuit diagram of a connection structure of a light-emitting diode package according to an exemplary embodiment of the present invention.

Referring to FIG. 6A, the light-emitting diode packages LDP may be connected in parallel to the first signal line 300-CL1 and the second signal line 300-CL2. In FIG. 6A, a region depicted by a dotted line may be a region corresponding to the first side surface SS1 (see, e.g. FIG. 4).

Referring to FIG. 6B, the first lead frame RD1 and the second lead frame RD2 of the light-emitting diode package LDP may be connected to the coupling portions 300-C, respectively. A coupling portion RD1-C (e.g., which may be referred to herein as a first lead coupling portion, or a first lead frame coupling portion) of the first lead frame RD1 and a coupling portion RD2-C (e.g., which may be referred to herein as a second lead coupling portion, or a second lead frame coupling portion) of the second lead frame RD2 may be coupled to the first signal line 300-CL1 and the second signal line 300-CL2, respectively, via solder pastes SP. However, a method of coupling the signal lines 300-CL1 and 300-CL2 to the light-emitting diode package is not limited to this example. For example, the solder paste SP may be omitted and an anisotropic conductive film may be employed, for example. The first lead coupling portion RD1-C and the second lead. coupling portion RD2-C may he disposed between the coupling portions 300-C and the mold MD.

The sealing element SL may be provided to be spaced apart from the first side surface SS1 by a predetermined distance. In an exemplary embodiment of the present invention, referring to FIG. 6C, the sealing element SL may be provided to be in direct contact with the first side surface SS1.

Since the light-emitting diode package LDP is coupled to the side surface of the light guiding structure LG, it may be possible to prevent the light guiding structure LG and the light-emitting diode package LDP from being misaligned to each other and to increase optical efficiency of the display device. In addition, it may be possible to omit an additional circuit board for mounting the .light-emitting diode package LDP. In this case, since a space for the circuit board is not included, the backlight unit 300 may be suitable for a display panel with a relatively slim bezel.

Referring to FIG. 6D, the light-emitting diode package LDP may include a heat dissipation unit HRP. The heat dissipation unit HRP may be coupled to a bottom surface of the mold MD. The heat dissipation unit HRP may be configured to transfer heat, which is produced in the light-emitting diode LD, to a cover unit 100 (e.g., the supporting frame 100M), and thus to lower the temperature of the light-emitting diode package LDP. In an exemplary embodiment of the present invention, the heat dissipation unit HRP may be formed of or include silicon, but exemplary embodiments of the present invention are not limited to the specific material for the heat dissipation unit HRP.

Referring to FIG. 6E, the light-emitting diode packages LDP may be connected in series. The first signal line 300-CL!. may include a plurality of portions 300-CL11 to 300-CL14. The first portion 300-CL11 may connect the first one of the light-emitting diode packages LDP to the circuit board FPC (see, e.g., FIG. 4), Other portions 300-CL12 to 300-CL14 may connect the light-emitting diode packages LDP to each other. The second signal line 300-CL2 may connect the last one of the light-emitting diode packages LDP to the circuit board FPC.

Additional signal lines may be further provided in the backlight unit 300. Signal line pairs corresponding to the light-emitting diode packages LDP, respectively, may allow the light-emitting diode packages LDP to perform a dimming operation.

According to an exemplary embodiment of the present invention, a light-emitting diode package may include the mold MD including the cavity CV formed in the mold MD The light-emitting diode LD may be disposed on the mold MD. The sealing element SL may be disposed on side surfaces of the cavity CV. The sealing element SL may substantially cover the light-emitting diode LD. The first lead frame RD1 may he disposed on the mold MD. The first lead frame RD1 may include the first lead frame coupling portion RD1-C disposed on a surface of the mold MD facing away from the light-emitting diode LD. The second lead frame RD2 may be disposed on the mold MD. The second lead frame RD2 may include the second lead frame coupling portion RD2-C disposed on the surface of the mold MD facing away from the light-emitting diode LD. The second lead frame coupling portion RD2-C may be spaced apart from the first lead frame coupling portion RD1-C.

In an exemplary embodiment of the present invention, the first lead frame coupling portion RD1-C or the second lead from coupling portion RD2-C may be in direct contact with a side surface of the sealing element SL.

For example, the light-emitting diode package LDP may he coupled to a side surface of the backlight unit 300 described herein (e.g., with little or no gap between the light source LES and the light guiding structure—see, e.g., FIG. 3), thus preventing misalignment between the light guiding structure LG and the light-emitting diode package LDP, which may increase optical efficiency of the backlight unit 300.

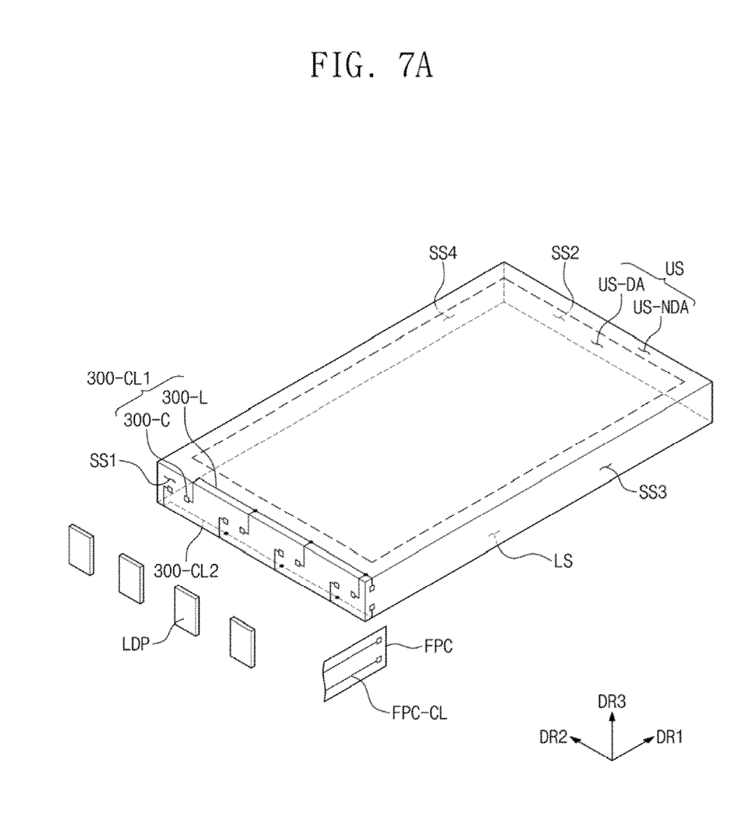

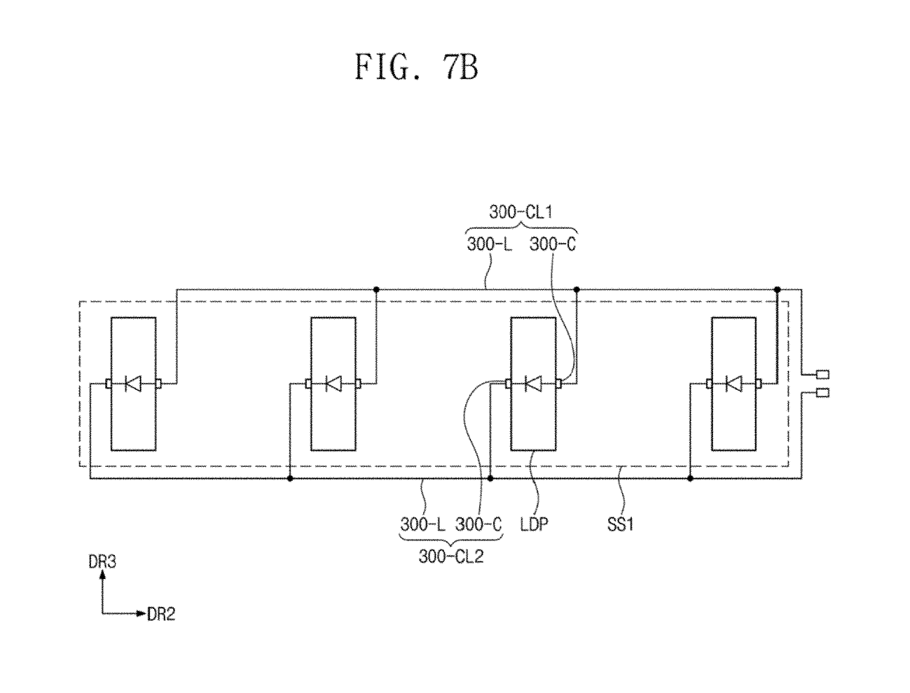

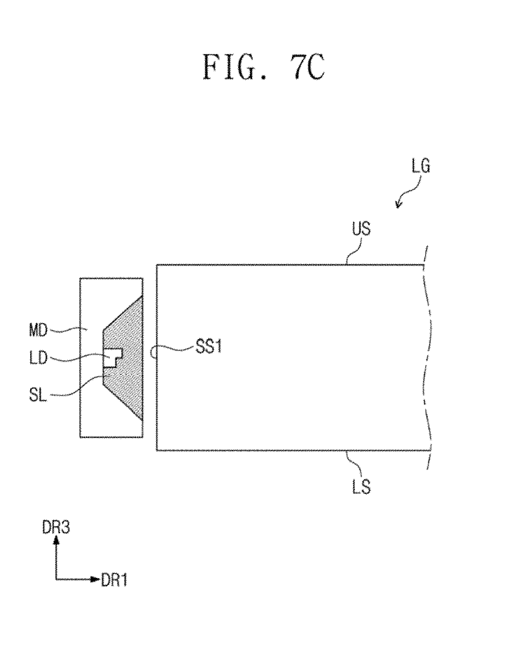

FIG. 7A is an exploded perspective view of a backlight unit according to an exemplary embodiment of the present invention. FIG. 7B is an equivalent circuit diagram of a connection structure of a light-emitting diode package according to an exemplary embodiment of the present invention. FIG. 7C is a cross-sectional view of a portion of a backlight unit according to an exemplary embodiment of the present invention. FIGS. 7A, 7B, and 7C may correspond to FIG. 4, 6A, and 6B, respectively. Thus, descriptions of components that are the same or substantially the same as those described above may be omitted below with reference to FIGS. 7A, 7B and

Referring to FIG. 7A, the first line portion 300-L of the first signal line 300-CL1 and the second line portion 300-L of the second signal line 300-CL2 may be disposed on the first surface US and the second surface LS, respectively. The first surface US may include a display region US-DA and a non-display region US NDA corresponding to the display region DA and the non-display region NDA, respectively, of the display panel DP (see, e.g., FIG. 2). As an example, the non-display region US-NDA may be arranged at four sides of the display region US-DA in a plan view; however, exemplary embodiments of the present invention are not limited thereto. For example, the non-display region US-NDA may be arranged at less than four sides (e.g., three sides) of the display region US-DA in a plan view.

The first line portion 300-L of the first signal line 300-CL1 may be overlapped with the non-display region US-NDA and might not be overlapped with the display region US-DA. For example, the first line portion 300-1, of the first signal line 300-CI,1 may be disposed on a portion of the first surface US, which is not overlapped with the optical sheets FS (see, e.g., FIG. 3). The second surface LS may also include a display region and a non-display region corresponding to the display region US-DA and the non-display region US-NDA, respectively, and the second line portion 300-L of the second signal line 300-CL2 may be disposed on the non-display region of the second surface LS.

Referring to FIGS. 7A to 7C, the coupling portion 300-C of the first signal line 300-CL1 may face the coupling portion 300-C of the second signal line 300-CL2 in the second direction DR2. As an example, the coupling portion 300-C might not be provided (e.g., may be omitted). When, on the first side surface SS1, the signal line is not provided in the third direction DR3, length (e.g., thickness) of the light-emitting diode package LDP in the third direction DR3 may be substantially equal to a length (e.g., thickness) of the first side surface SS1 in the third direction DR3. An area of an emission surface of the light-emitting diode package LDP facing the first side surface SS1 may be increased, and thus optical efficiency of light to be incident into the light guiding structure LG may be increased. For example, the light-emitting diode package LDP may be coupled to a side surface of the backlight unit 300 described herein (e.g., with little or no gap between the light source LES and the light guiding structure—see, e.g., FIG. 3), thus preventing misalignment between the light guiding structure LG and the light-emitting diode package LDP, which may increase optical efficiency of the backlight unit 300.

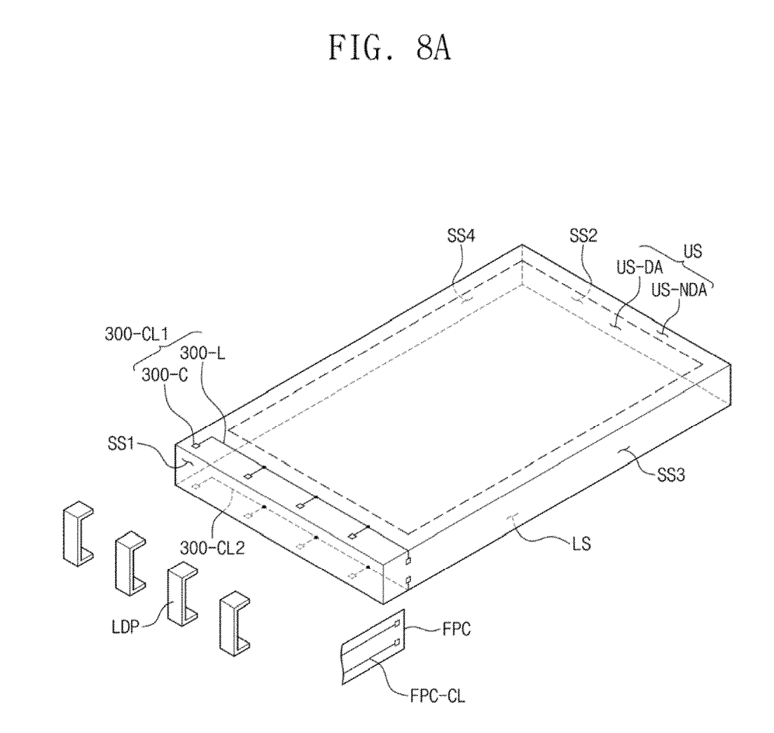

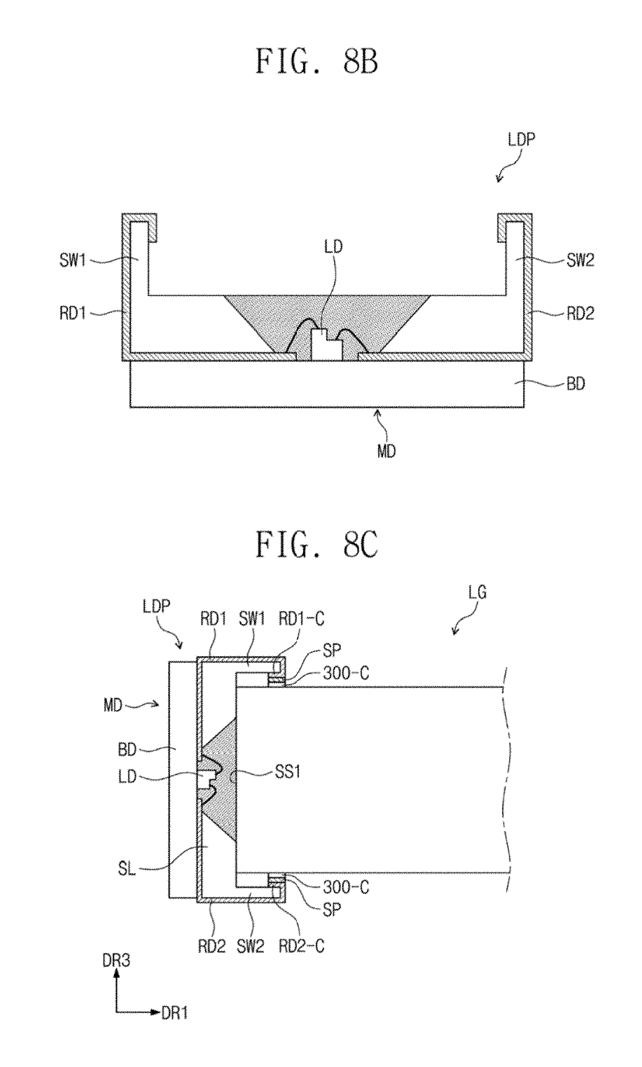

FIG. 8A is an exploded perspective view of a backlight unit according to an exemplary embodiment of the present invention, FIG. 8B is a cross-sectional view of a light-emitting diode package according to an exemplary embodiment of the present invention. FIG. 8C is a cross-sectional view of a portion of a backlight unit according to an exemplary embodiment of the present invention. FIGS. 8A, 8B, and 8C may correspond to FIGS. 4, 5B, and 6B, respectively. Thus, descriptions of components that are the same or substantially the same as those described above may be omitted below with reference to FIGS. 8A, 8B and 8C.

Referring to FIG. 8A, the first line portion 300-L and the first coupling portion 300-C of the first signal line 300-CL1 may be disposed on the first surface US, and the second line portion 300-L and the second coupling portion 300-C of the second signal line 300-CL2 may be disposed on the second surface LS. The first line portion 300-L and the first coupling portion 300-C of the first signal line 300-CL1 may be overlapped with the non-display region US-NDA. .A portion of the first signal. line 300-CL1 coupled to the circuit board FPC may be disposed on the third side surface SS3, but exemplary embodiments of the present invention are not limited thereto. For example, the entire first line portion 300-L of the first signal line 300-CL1 may be disposed on the first surface US. Further, the entire second line portion 300L of the second. signal line 300-CL2 may be disposed on the second surface LS.

Referring to FIG. 8B, the mold MD may include a body portion BD and sidewall portions SWI and SW2. The body portion BD may correspond to the mold MD (see, e.g., FIGS. 5A and 5B). The sidewall portions SW1 and SW2 may be spaced apart from each other and may be provided to having a shape protruding from the mold MD and to face each other.

Referring to FIG. 8C, when the light-emitting diode package MP is coupled to the light guiding structure LG, a first sidewall portion SW1 may face the first surface US and a second sidewall portion SW2 may face the second surface LS. The first lead frame RD1 may be fixed to the body portion BD, and a portion of the first lead frame RD1 may be disposed on an outer surface of the mold MD (e.g., a surface facing away from the light guiding structure LG). The first lead frame RD1 may further include a portion that is extended to cover the first sidewall portion SW1. The first lead coupling portion RD1-C may be disposed on an inner surface of the first sidewall portion SWI (e.g., a surface facing the first surface US of the light guide structure LG). The first lead coupling portion RD1-C may be coupled to the coupling portion 300-C of the first signal line 300-CL1. disposed on the first surface US. The second lead frame RD2 may have a shape corresponding to the first lead frame RD1 (e.g., a mirror image shape with respect to the first lead frame RD1), and the second lead coupling portion RD2-C disposed on an inner surface of the second sidewall portion SW2 may he coupled to the coupling portion 300-C of the second signal line 300-CL2.

According to an exemplary embodiment of the present invention, a coupling strength between the light-emitting diode package LDP and the light guiding structure LG may he increased. Further, the light-emitting diode package LDP may be provided to he relatively close to or in direct contact with the first side surface SS1, For example, the light-emitting diode package LDP may he coupled to a side surface of the backlight unit 300 described herein (e.g., with little or no gap between the light source LES and the light guiding structure—see, e.g., FIG. 3), thus preventing misalignment between the light guiding structure LG and the light-emitting diode package LDP, which may increase optical efficiency of the backlight unit 300.

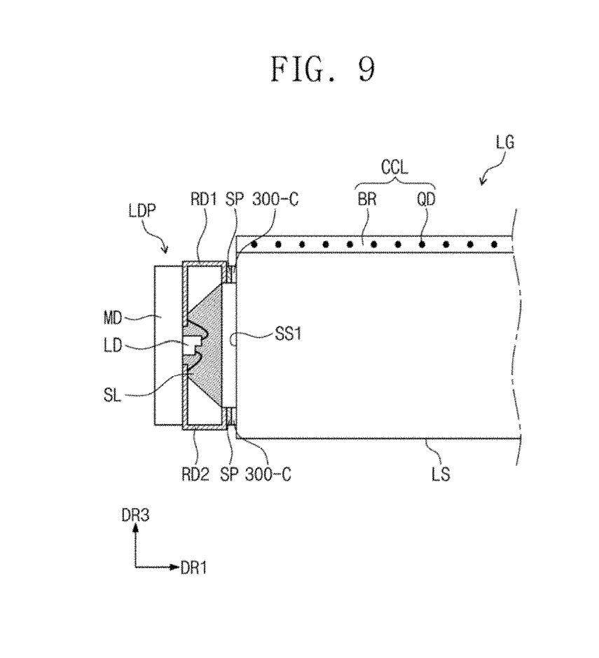

FIG. 9 is a cross-sectional view of a portion of a backlight unit according to an exemplary embodiment of the present invention. Descriptions of components that are the same or substantially the same as those described above may be omitted below with reference to FIG. 9.

Referring to FIG. 9, the light-emitting diode package LDP may be configured to generate a colored light. For example, the light-emitting diode package LDP may be configured to generate a blue light. The blue light may have a wavelength ranging from 410 nm to 480 nm and may have a peak wavelength ranging from 440 nm to 460 nm.

The backlight unit 300 may further include a color conversion layer CCL disposed on the first surface US. The color conversion layer CCL may be directly formed on the first surface US or may be disposed in the form of a sheet. The color conversion layer CCL may include a base resin BR, and a plurality of quantum dots QD, which are distributed in the base resin BR. The quantum dots QD may include a first quantum dot absorbing a blue light and emitting a green light and a second quantum dot absorbing a blue light and emitting a red light.

In an exemplary embodiment of the present invention, the sealing element SL may include a sealing material. The sealing element SL may further include a fluorescent material mixed with the sealing material. The fluorescent material may include one of a red fluorescent material, which absorbs a blue light and then emits a red light, and a green fluorescent material, which absorbs a blue light and then emits a green light.

In the case where the sealing element SL includes the red fluorescent material, the color conversion layer CCL may include quantum dots QD absorbing a blue light and then emitting a green light. In the case where the sealing element SL includes a green fluorescent material, the color conversion layer CCL may include quantum dots QD absorbing the blue light and then emitting a red light.

FIG. 10 is a cross-sectional view of a display device according to an exemplary embodiment of the present invention. Descriptions of components that are the same or substantially the same as those described above may be omitted below with reference to FIG. 10.

Referring to FIG. 10, the display device DD may include the cover unit 100 and the display panel 200. In an exemplary embodiment of the present invention, a single cover unit 100 may be provided, but the display device DD may include a plurality of portions which may be connected with each other. For example, a top and a bottom cover may be combined to form a cover unit,

In an exemplary embodiment of the present invention, the light guiding structure LG. described with reference to FIGS. 1 to 9 may be omitted, and a first base substrate BS1 of the display panel 200 may be used instead of the light guiding structure LG. The light-emitting diode package LDP may be coupled to a corresponding surface of surfaces of the first base substrate BS1. For example, the light-emitting diode package LDP may be in direct contact with a side surface of the base substrate BS1.

The light-emitting diode package LDP may be disposed on the first side surface SS1 of the first base substrate BS1. Signal lines may be directly disposed on the first base substrate BS1. The arrangement of the light guiding structure LG and the signal lines described with reference to FIGS. 1 to 8C may be applied to the first base substrate BS1 according to an exemplary embodiment of the present invention.

The color conversion layer CCL may be disposed on the first surface US of the first base substrate BS1. The color conversion layer CCL may be formed by a coating process. The color conversion layer CCL and the sealing element SL in the light-emitting diode package LDP described with reference to FIG. 9 may be applied to the display device DD described with reference to FIG. 10 in the same manner as described above.

A low refraction layer LRL may be disposed on the first surface US (e.g., may be formed before the formation of the color conversion layer CCL). The low refraction layer LRL may be an inorganic layer having a refractive index ranging from 1.2 to 1.4. A light condensing layer LDL may be disposed on the low refraction layer LRL. The light condensing layer may include an optical pattern condensing the light in a direction of the first surface US. The light condensing layer LDL may be coupled to (e.g., may be in direct contact with) the color conversion layer CCL (e.g., in the form of a sheet). The light condensing layer LDL may be formed at substantially the same time as the color conversion layer CCL through a single continuous process, or may be formed on the color conversion layer CCL through a successive process.

A first polarization layer PL1 may be disposed on the light condensing layer LDL. The first polarization layer PL1 may be directly formed on the light condensing layer LDL using a coating or deposition process and a patterning process. The first polarization layer PL1 may include wire grid patterns. A first structure layer ST1 may be disposed on the first polarization layer PL1. The first structure layer ST1 may include an insulating layer, or insulating layers which are stacked (eog., through a successive process). The first structure layer ST1 may further include a conductive layer. The first structure layer ST1 may include a color filter. A stacking structure from the first base substrate BS1 to the first structure layer ST1 may be defined as a first display substrate DS1.

A second polarization layer PL2 may be disposed on a top surface of a second base substrate BS2. The second polarization layer PL2 may be formed using a coating or deposition process and a patterning process. The second polarization layer PL2 may be a polarization film, which is separately manufactured and is attached to the second base substrate BS2.

A second structure layer ST2 may include an insulating layer, or insulating layers, which are stacked on a bottom surface of the second base substrate BS2 (e.g., by a successive process), The second structure layer ST2 may further include a conductive layer. The second structure layer ST2 may include transistors, signal lines, and/or pixel electrodes. A stacking structure from the second polarization layer PL2 to the second structure layer ST2 may be defined as a second display substrate DS2.

A liquid crystal layer LCL may be disposed between the first and second display substrates DS1 and. DS2. A sealant STL may maintain a cell gap between the first and second display substrates DS1 and DS2. The sealant STL may be provided along edge regions of the first and second display substrates DSI and DS2. The first structure layer ST1, the second structure layer ST2, and the liquid crystal layer LCL may include elements forming a liquid crystal capacitor.

Since the light-emitting diode package LDP is disposed on the first side surface SS1 of the first base substrate BS1, as described herein, the display device DD may be formed to have a relatively slim structure with increased optical efficiency.

According to an exemplary embodiment of the present invention, a light-emitting diode package is coupled to a side surface of a light guiding structure, and this may prevent misalignment between the light guiding structure and the light-emitting diode package and may increase optical efficiency of a backlight unit. In addition, the backlight unit described herein may be suitable for a display panel with a relatively slim bezel.

A heat dissipation unit may be used to transfer heat, which is generated in the light-emitting diode package, to a. protection. cover, and thus, heat dissipation efficiency of the display panel may be increased.

While the present invention has been shown and described with reference to the exemplary embodiments thereof, it will he apparent to those of ordinary skill in the art that various changes in form and detail may be made thereto without departing from the spirit and scope of the present invention.

What is claimed is:

1. A display device, comprising:
a display panel;
a backlight unit adjacent to the display panel; and
a cover unit adjacent to the display panel and the backlight unit,
wherein the backlight unit comprises:
a light guiding structure comprising a first surface and a second surface facing each other in a thickness direction of the display panel and side surfaces connecting the first surface to the second surface;
signal lines directly disposed on the first surface, the second surface, or a side surface of the side surfaces; and
a light-emitting diode package coupled to the signal lines and positioned to provide light to a first side surface of the side surfaces.

2. The display device of claim 1, wherein the signal lines comprise:
a first signal line; and
a second signal line spaced apart from the first signal line,
wherein a portion of the first or second signal lines is disposed on the first side surface, and
the light-emitting diode package is coupled to the portion of the first or second signal lines disposed on the first side surface.

3. The display device of claim 1, wherein the signal lines comprise:
a first signal line; and
a second signal line spaced apart from the first signal line,
wherein the first signal line comprises a first line portion disposed on the first surface and a first coupling portion disposed on the first side surface,
the second signal line comprises a second line portion disposed on the second surface and a second coupling portion disposed on the first side surface, and
the light-emitting diode package is coupled to the first coupling portion and the second coupling portion.

4. The display device of claim 3, wherein the first side surface is defined by the thickness direction of the display panel and a length direction crossing the thickness direction of the display panel, and
the first coupling portion and the second coupling portion are spaced apart from each other in the length direction.

5. The display device of claim 3, wherein the display panel comprises a display region, on which pixels are disposed, and a non-display region, on whiCh the pixels are not disposed, and
the first line portion and the second line portion are overlapped with the non-display region.

6. The display device of claim 1, wherein the light-emitting diode package comprises:
a mold, in which a cavity is defined;
a light-emitting diode disposed in the cavity and including a first electrode and a second electrode;
a sealing element substantially covering the light-emitting diode;
a first lead frame connected to the first electrode and including a first lead coupling portion disposed on an outer surface of the mold; and
a second lead frame connected to the second electrode and including a second lead coupling portion disposed on the outer surface of the mold.

7. The display device of claim 6, further comprising a solder paste connecting the first lead coupling portion and the second lead coupling portion to the signal lines.

8. The display device of claim. 7, wherein the first lead coupling portion and the solder paste are disposed between a corresponding signal line of the signal lines and the mold.

9. The display device of claim 6, wherein the light-emitting diode package further comprises a heat dissipation unit coupled to the mold and in direct contact with the cover unit.

10. The display device of claim 1, wherein the signal lines comprise:
a first signal line comprising a first line portion disposed on the first surface and a first coupling portion disposed on the first surface; and
a second signal line comprising a second line portion disposed on the second surface and a second coupling portion disposed on the second surface,
wherein the light-emitting diode package is coupled to the first coupling portion and the second coupling portion.

11. The display device of claim 10, wherein the light-emitting diode package comprises:
a mold, in which a cavity is defined, the mold comprising a body portion, and a first sidewall portion and a second sidewall portion, which. are connected to the body portion and are overlapped with the first surface and the second surface, respectively;
a light-emitting diode disposed in the cavity, the light-emitting diode including a first electrode and a second electrode;
a sealing element substantially covering the light-emitting diode;
a first lead frame disposed on the first sidewall portion and electrically connecting the first electrode to the first coupling portion; and
a second lead frame disposed on the second sidewall portion and electrically connecting the second electrode to the second coupling portion.

12. The display device of claim 11, wherein a portion of the first lead frame is disposed on an inner surface of the first sidewall portion facing the first surface, and a portion of the second lead frame is disposed on an inner surface of the second sidewall portion facing the second surface.

13. The display device of claim 10, wherein the display panel comprises a display region, on which pixels are disposed, and a non-display region, on which the pixels are not disposed, and
the first signal line and the second signal line are overlapped with the non-display region.

14. The display device of claim 1, further comprising a circuit hoard, which is configured to provide a first voltage and a second voltage, which are different from each other, to the signal lines,
wherein the signal lines comprise:
a first signal line, to which the first voltage is applied; and
a second signal line, to which the second voltage is applied,
wherein each of the first signal line and the second signal line comprises a coupling portion coupled to the circuit board, and
the coupling portion is disposed on a second side surface of the side surfaces adjacent to the first side surface.

15. The display device of claim 1, wherein the light guiding structure comprises a glass substrate,

16. The display device of claim 1, further comprising a color conversion layer, which is disposed between the display panel and the light guiding structure and includes a quantum dot.

17. The display device of claim 16, wherein the light-emitting diode package is configured to emit a blue light, and
the quantum dot comprises a first quantum dot, which is configured to absorb the blue light and emit a green light, and a second quantum dot, which is configured to absorb the blue light and emit a red light.

18. The display device of claim 16, wherein the light-emitting diode package is configured to emit a blue light,
the light-emitting diode package comprises a light-emitting diode and a sealing element covering the light-emitting diode, and
the sealing element comprises a fluorescent material, which is mixed therein and is configured to absorb the blue light and emit one of red or green lights,
wherein the quantum dot is configured to absorb the blue light and to emit the other of the red or green lights.

19. A display device, comprising:
a first base substrate comprising a first surface and a second surface facing each other in a thickness direction and side surfaces connecting the first surface to the second surface to each other;
a second base substrate disposed on the first base substrate;
a liquid crystal layer disposed between the first base substrate and the second base substrate;
signal lines directly disposed on the first surface, the second surface, or a corresponding side surface of the side surfaces; and
a light-emitting diode package coupled to the signal lines and positioned to provide light to a side surface of the side surfaces.

20. The display device of claim 19, wherein the light-emitting diode package comprises:
a mold, in which a cavity is defined;
a light-emitting diode disposed in the cavity, the light-emitting diode comprising a first electrode and a second electrode;
a sealing element substantially covering the light-emitting diode;
a first lead frame connected to the first electrode, the first lead frame comprising a first lead coupling portion, which is disposed on a surface of the mold and is coupled to a first signal line of the signal lines; and
a second lead frame connected to the second electrode, the second lead frame comprising a second lead coupling portion, which is disposed on the surface of the mold and is coupled to a second signal line of the signal lines.

21. A light-emitting diode package, comprising:
a mold comprising a cavity formed in the mold;
a light-emitting diode disposed on the mold;
a sealing element disposed on side surfaces of the cavity, wherein the sealing element substantially covers the light-emitting diode;
a first lead frame disposed on the mold, wherein the first lead frame comprises a first lead frame coupling portion disposed on a surface of the mold facing away from the light-emitting diode; and
a second lead frame disposed on the mold, wherein the second lead frame comprises a second lead frame coupling portion disposed on the surface of the mold facing away from the light-emitting diode, wherein the second lead frame coupling portion is spaced apart from the first lead frame coupling portion.

22. The light-emitting diode package of claim 21, wherein the first lead frame coupling portion or the second lead frame coupling portion is in direct contact with a side surface of the sealing element.
